(19) United States
(12) Patent Application Publication
(10) Pub. No.: US 2024/0008297 A1
(43) Pub. Date: Jan. 4, 2024

(54) IMAGING DEVICE AND METHOD FOR MANUFACTURING IMAGING DEVICE

(71) Applicant: Panasonic Intellectual Property Management Co., Ltd., Osaka (JP)

(72) Inventor: DAISUKE WAKABAYASHI, Osaka (JP)

(21) Appl. No.: 18/468,719

(22) Filed: Sep. 17, 2023

Related U.S. Application Data
(63) Continuation of application No. PCT/JP2022/011258, filed on Mar. 14, 2022.

(30) Foreign Application Priority Data
Apr. 12, 2021 (JP) 2021-067279

(51) Int. Cl. H10K 39/32

(52) U.S. Cl. CPC H10K 39/32

(57) ABSTRACT

An imaging device includes a semiconductor substrate, a first photoelectric converter located above the semiconductor substrate and converting light having a wavelength in a first wavelength range into first charge, and a second photoelectric converter located above the first photoelectric converter and converting light having a wavelength in a second wavelength range into second charge. The first photoelectric converter includes a first pixel electrode, a first counter electrode facing the first pixel electrode, and a first photoelectric conversion layer located between the first pixel electrode and the first counter electrode. The imaging device further includes a plug that penetrates the first photoelectric conversion layer and that is connected to the second photoelectric converter and an insulating layer that is located between the first photoelectric conversion layer and the plug and that covers a side surface of the plug. The insulating layer has a tapered shape that tapers upward.

### BACKGROUND

### 1. Technical Field

The present disclosure relates to an imaging device and a method for manufacturing an imaging device.

### 2. Description of the Related Art

An image sensor includes a photodetection element that generates an electrical signal in accordance with the amount of incident light and has a plurality of pixels arranged in one or two dimensions. A stacked image sensor is an image sensor that has, as a pixel, a photodetection element having a structure in which a photoelectric conversion film is stacked above a substrate. For example, a stacked image sensor is described in Japanese Unexamined Patent Application Publication No. 2019-16667. In addition, Japanese Unexamined Patent Application Publication No. 2005-340571 describes a stacked image sensor with a plurality of photoelectric conversion films stacked on top of each other.

### SUMMARY

In one general aspect, the techniques disclosed here feature an imaging device including a semiconductor substrate, a first photoelectric converter that includes a first pixel electrode, a first counter electrode facing the first pixel electrode, and a first photoelectric conversion layer located between the first pixel electrode and the first counter electrode, the first photoelectric converter being located above the semiconductor substrate and converting first light having a wavelength in a first wavelength range into first charge, a second photoelectric converter that is located above the first photoelectric converter and that convers second light having a wavelength in a second wavelength range into second charge, a plug that penetrates through the first photoelectric conversion layer and that is connected to the second photoelectric converter, and an insulating layer that is located between the first photoelectric conversion layer and the plug and that covers a side surface of the plug. The insulating layer has a tapered shape that tapers upward toward the second photoelectric converter.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic illustration of the circuit configuration of an imaging device according to an embodiment;

FIG. 2 is a schematic cross-sectional view of the cross-sectional structure of a pixel of the imaging device according to the embodiment;

FIG. 3 is a plan view of the electrode layout in the pixel of the imaging device according to the embodiment;

FIG. 4 is a cross-sectional view of a photoelectric converter of the pixel taken along line IV-IV of FIG. 3;

FIG. 5A is a cross-sectional view illustrating one process of a method for manufacturing the imaging device;

FIG. 5B is a cross-sectional view illustrating one process of the method for manufacturing the imaging device;

FIG. 5C is a cross-sectional view illustrating one process of the method for manufacturing the imaging device;

FIG. 5D is a cross-sectional view illustrating one process of the method for manufacturing the imaging device;

FIG. 5E is a cross-sectional view illustrating one process of the method for manufacturing the imaging device;

FIG. 5F is a cross-sectional view illustrating one process of the method for manufacturing the imaging device;

FIG. 5G is a cross-sectional view illustrating one process of the method for manufacturing the imaging device;

FIG. 5H is a cross-sectional view illustrating one process of the method for manufacturing the imaging device;

FIG. 5I is a cross-sectional view illustrating one process of the method for manufacturing the imaging device;

FIG. 6 is a cross-sectional view of a plug that penetrates through a photoelectric conversion layer of the imaging device according to Modification 1;

FIG. 7 is a cross-sectional view of a plug that penetrates through a photoelectric conversion layer of the imaging device according to Modification 2;

FIG. 8 is a cross-sectional view of a plug that penetrates through a photoelectric conversion layer of the imaging device according to Modification 3; and

FIG. 9 is a cross-sectional view of a plug that penetrates through a photoelectric conversion layer of the imaging device according to Modification 4.

### DETAILED DESCRIPTIONS

### Underlying Knowledge Forming Basis of the Present Disclosure

In a structure in which a plurality of photoelectric conversion films are stacked, as in the imaging device disclosed in Japanese Unexamined Patent Application Publication No. 2005-340571, it is necessary to form vertical wiring that penetrates through the photoelectric conversion film in the lower layer and is connected to the photoelectric conversion film in the upper layer. More specifically, after forming the photoelectric conversion film, openings are formed in the photoelectric conversion film, and an insulating film is formed to fill the formed openings. Furthermore, openings for vertical wiring are formed in a portion of the insulating film that fills the openings, and vertical wiring is formed in the formed openings.

However, in this process, etching damage occurs to the photoelectric conversion film when openings are formed in the photoelectric conversion film, which raises concerns about degradation of the performance of the photoelectric conversion film.

To address the issue, after forming vertical wiring and an insulating film covering the side surface of the vertical wiring, a photoelectric conversion film can be formed using a coating material. However, when, for example, the coating film is formed by spin coating, the coating material rides up and remains on the top of the vertical wiring. Therefore, processing to remove the remaining coating film is required.

Examples of processing to remove the remaining coating film include etch-back using oxygen plasma and polishing by CMP (Chemical Mechanical Polishing). However, in the case of etch-back using oxygen plasma, the photoelectric conversion film is exposed to oxygen, which may degrade the performance of the photoelectric conversion film. In the case of polishing by CMP, mechanical damage to the film interface occurs due to polishing stress, which may degrade the performance of the photoelectric conversion film.

As described above, in existing technologies, there is a risk of performance degradation of the photoelectric conversion film, making it difficult to achieve a high-performance imaging device.

In contrast, an imaging device according to an aspect of the present disclosure includes a semiconductor substrate, a first photoelectric converter, a second photoelectric converter, a plug, and an insulating layer. The first photoelectric converter is located above the semiconductor substrate and converts first light having a wavelength in a first wavelength range into first charge. The second photoelectric converter is located above the first photoelectric converter and converts second light having a wavelength in a second wavelength range into second charge. The first photoelectric converter includes a first pixel electrode, a first counter electrode facing the first pixel electrode, a first photoelectric conversion layer located between the first pixel electrode and the first counter electrode. The plug penetrates through the first photoelectric conversion layer and is connected to the second photoelectric converter. The insulating layer is located between the first photoelectric conversion layer and the plug and covers a side surface of the plug. The insulating layer has a tapered shape that tapers upward toward the second photoelectric converter. In addition, for example, the first photoelectric conversion layer may contain an organic substance.

According to the aspect, since the insulating layer that covers the side surface of the plug has a tapered shape that tapers upward, the areas of flat regions of the upper surfaces of the plug and the insulating layer are relatively small. Therefore, there is little risk that the coating film remains on the flat regions. Even if the coating film remains on the upper surfaces of the plug and the insulating layer immediately after a coating process, the coating film is expected to slide down via the inclined side surface of the insulating layer due to the centrifugal force generated during spin coating and the re-flow of the coating film during a coating film drying process.

Thus, the first photoelectric conversion layer having a flat upper surface can be formed without performing an additional process for removing the coating film on the upper surfaces of the plug and the insulating layer. More specifically, etching to form an opening in the first photoelectric conversion layer or polishing or etch-back for planarizing the first photoelectric conversion layer is not needed. For this reason, performance degradation of the first photoelectric conversion layer is less likely to occur, and thus a high-performance imaging device can be achieved.

For example, the second photoelectric converter may include a second pixel electrode, a second counter electrode located above the second pixel electrode, and a second photoelectric conversion layer located between the second pixel electrode and the second counter electrode, and the plug may be connected to the second pixel electrode.

For example, each of the first counter electrode, the second pixel electrode, and the second counter electrode may have a property of at least partially transmitting the first light.

This reduces the attenuation of the first light by the first counter electrode, the second pixel electrode, and the second counter electrode. As a result, the photoelectric conversion efficiency of the first photoelectric conversion layer can be increased.

For example, the imaging device according to the aspect of the present disclosure may further include a charge storage region that is located in the semiconductor substrate and that stores the second charge, and the second photoelectric converter may be connected to the charge storage region via the plug.

This allows the signal charge generated in the second photoelectric conversion layer to be temporarily stored, and the stored signal charge can be read out and processed at a desired point in time.

For example, the upper surface of the plug may be located above the upper surface of the first photoelectric conversion layer.

This eliminates the need for a planarization process or the like between the upper surface of the plug and the upper surface of the first photoelectric conversion layer, thus facilitating the manufacturing of the imaging device.

For example, the imaging device according to the aspect of the present disclosure may further include a via connected to the lower end of the plug, and the width of the plug may be less than the width of the via.

Thus, the coating film is less likely to remain on the top of the plug and the top of the insulating layer because the plug is thin. Therefore, no treatment for planarization or the like is required, and performance degradation of the first photoelectric conversion layer is less likely to occur, enabling a high-performance imaging device to be achieved.

An imaging device according to another aspect of the present disclosure includes a semiconductor substrate, a first photoelectric converter, a second photoelectric converter, and a plug. The first photoelectric converter is located above the semiconductor substrate and converts first light having a wavelength in a first wavelength range into first charge. The second photoelectric converter is located above the first photoelectric converter and converts second light having a wavelength in a second wavelength range into second charge. The first photoelectric converter includes a first pixel electrode, a first counter electrode facing the first pixel electrode, and a first photoelectric conversion layer located between the first pixel electrode and the first counter electrode. The plug penetrates through the first photoelectric conversion layer and is connected to the second photoelectric converter. The plug has a tapered shape that tapers upward toward the second photoelectric converter.

According to an aspect of the present disclosure, a method for manufacturing an imaging device is a method for manufacturing the above-described imaging device, and the method includes applying a photoelectric conversion material to form the first photoelectric conversion layer.

According to another aspect of the present disclosure, a method for manufacturing an imaging device includes forming, on a semiconductor substrate, a plug and an insulating layer that covers a side surface of the plug, processing the insulating layer so that the insulating layer tapers upward, and forming a photoelectric conversion layer by applying a photoelectric conversion material such that a height of the photoelectric conversion material is the same as the height of the plug and the insulating layer.

In the forming of the plug and the insulating layer, the plug may be formed by depositing the insulating layer, forming a hole in the insulating layer, and embedding a conductive material in the hole.

The hole may be formed in the insulating layer by etching.

The processing of the insulating layer may be performed by dry etching.

The forming of the photoelectric conversion layer may be performed by spin coating. The forming of the plug and the insulating layer, the processing of the insulating layer, and the forming of the photoelectric conversion layer may be performed in this order.

Exemplary embodiments are described in detail below with reference to the accompanying drawings.

Note that each of the embodiments described below is a general or specific example of the present disclosure. A value, a shape, a material, a constituent element, the positions and the connection form of the constituent elements, steps, and the sequence of steps described in the embodiments are only examples and shall not be construed as limiting the scope of the present disclosure. In addition, among the constituent elements in the embodiments described below, the constituent element that does not appear in an independent claim, which has the broadest scope, is described as an optional constituent element.

All the drawings are schematic and not necessarily to scale. Therefore, for example, the scales may differ between figures. Substantially the same configurations between the figures are identified by the same reference numerals, and duplicate description may be omitted or simplified.

As used herein, the terms associated with relationships between elements, such as “parallel” and “perpendicular”, the terms associated with the shape of elements, such as “circular” and “square”, and numerical ranges are not used in a strict sense but used in a broader sense (in a substantially equivalent range, for example, with a tolerance of several percents).

As used herein, the terms “above” and “below” do not refer to the upward (vertical upward) and downward (vertical downward) directions in absolute spatial awareness but are used as terms defined by relative positional relationships based on the stacking order in a stacked structure. That is, in actual use, the term “upward” as used herein does not necessarily correspond to vertical above, but may correspond to vertical below, horizontal, or diagonal to vertical or horizontal, and the direction is not limited.

As used herein, the terms “above” and “below” are applicable not only when two constituent elements are disposed with a space therebetween and another constituent element is present between the two constituent elements, but also when the two constituent elements are placed in tight contact with each other and, thus, the two constituent elements touch.

As used herein, the x-axis, y-axis, and z-axis refer to the three axes of a three-dimensional Cartesian coordinate system. The x-axis and y-axis correspond to two directions that are parallel to the principal surface of the semiconductor substrate and mutually perpendicular. The z-axis corresponds to a direction perpendicular to the principal surface of the semiconductor substrate. The direction perpendicular to the principal surface of the semiconductor substrate is also referred to as the thickness direction or the stacking direction. As used herein, the term “plan view” refers to a view of the principal surface of the semiconductor substrate from the front, that is, from a direction perpendicular to the principal surface of the semiconductor substrate.

### EMBODIMENTS

### 1. Circuit Configuration of Imaging Device

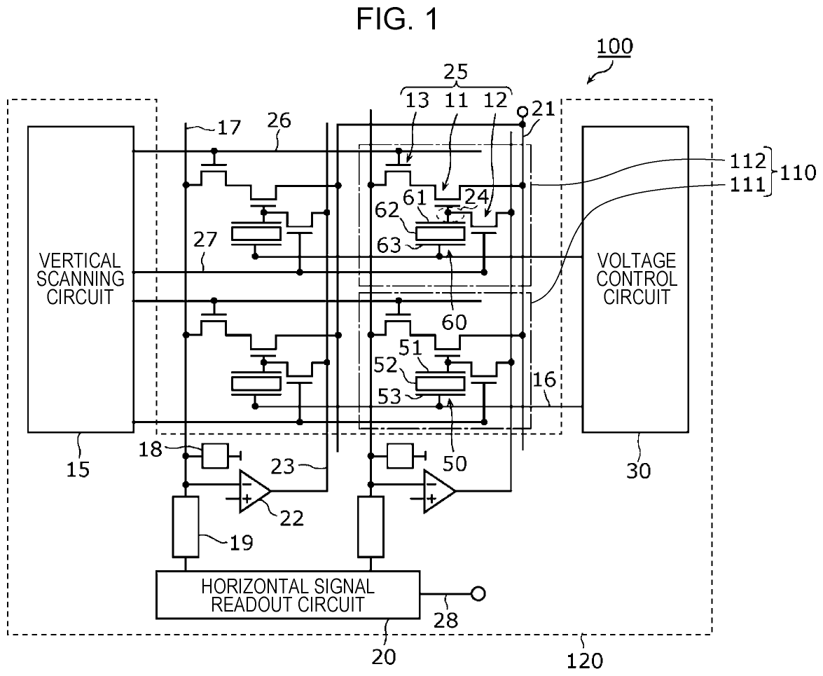

The overview of the circuit configuration of an imaging device is first described with reference to FIG. 1.

FIG. 1 is a schematic illustration of the circuit configuration of an imaging device 100. As illustrated in FIG. 1, the imaging device 100 includes a plurality of pixels 110 and a peripheral circuit 120.

The plurality of pixels 110 are arranged on the semiconductor substrate two-dimensionally, that is, in the row and column directions, and form a pixel region. The plurality of pixels 110 may be arranged in a single row. That is, the imaging device 100 may be a line image sensor. As used herein, the terms “row direction” and “column direction” refer to the directions in which the rows and columns extend, respectively. More specifically, the vertical direction in FIG. 1 is the column direction, and the horizontal direction is the row direction.

Each of the pixels 110 includes a plurality of sub-pixels 111 and 112. The sub-pixels 111 and 112 each receive light having a wavelength in a predetermined wavelength range and generate an electrical signal corresponding to the intensity of the received light. More specifically, sub-pixels 111 and 112 each include a photoelectric converter 50 or 60 and a charge detection circuit 25. The photoelectric converter 50 includes a pixel electrode 51, a photoelectric conversion layer 52, and a transparent electrode 53. The photoelectric converter 60 includes a pixel electrode 61, a photoelectric conversion layer 62, and a transparent electrode 63. Particular configurations of the photoelectric converters 50 and 60 are described below. The charge detection circuit 25 includes an amplifier transistor 11, a reset transistor 12, and an address transistor 13.

The imaging device 100 includes a voltage control element for applying a predetermined voltage to the transparent electrodes 53 and 63. The voltage control element includes, for example, a voltage control circuit, a voltage generating circuit, such as a constant voltage source, and a voltage reference line, such as a ground line. The voltage applied by the voltage control element is referred to as a “control voltage”. According to the present embodiment, the imaging device 100 includes a voltage control circuit 30 as the voltage control element.

The voltage control circuit 30 may generate a constant control voltage or may generate a plurality of control voltages of different values. For example, the voltage control circuit 30 may generate control voltages of two or more different values or may generate a control voltage that varies continuously within a predetermined range. The voltage control circuit 30 determines the value of the control voltage to be generated on the basis of a command received from an operator operating the imaging device 100 or a command received from another controller or the like provided in the imaging device 100 and generates a control voltage of the determined value. The voltage control circuit 30 is provided outside a photosensitive region as a part of the peripheral circuit 120. The photosensitive region is substantially the same as the pixel region.

According to the present embodiment, as illustrated in FIG. 1, the voltage control circuit 30 applies a control voltage to the transparent electrodes 53 or 63 of the pixel 110 arranged in the row direction via a counter electrode signal line 16. Thus, the voltage control circuit 30 changes the voltage between the pixel electrode 51 and the transparent electrode 53 or between the pixel electrode 61 and the transparent electrode 63 to switch the spectral sensitivity characteristics of the photoelectric converter 50 or 60.

For example, to store electrons as signal charge in the pixel electrode 61 when light is emitted to the photoelectric converter 60, the pixel electrode 61 is set to a potential higher than the transparent electrode 63. At this time, since the movement direction of the electrons is opposite to that of holes, a current flows from the pixel electrode 61 toward the transparent electrode 63. In addition, to store holes as signal charge in the pixel electrode 61 when light is emitted to the photoelectric converter 60, the pixel electrode 61 is set to a potential lower than the transparent electrode 63. At this time, a current flows from the transparent electrode 63 to the pixel electrode 61.

The same applies to the photoelectric converter 50 as to the photoelectric converter 60. The configuration of the charge detection circuit 25 connected to the photoelectric converter 50 is the same as that of the charge detection circuit 25 connected to the photoelectric converter 60. Hereinafter, description is made with reference to the photoelectric converter 60 and the charge detection circuit 25 connected to the photoelectric converter 60, that is, the circuit configuration of the sub-pixel 112.

The pixel electrode 61 is connected to the gate electrode of amplifier transistor 11, and the signal charge collected by pixel electrode 61 is stored in charge storage node 24 located between the pixel electrode 61 and the gate electrode of the amplifier transistor 11. The charge storage node 24 is an example of a charge storage region. According to the present embodiment, the signal charge is hole. However, the signal charge may be electron.

The signal charge stored in the charge storage node 24 is applied to the gate electrode of the amplifier transistor 11 in the form of a voltage corresponding to the amount of the signal charge. The amplifier transistor 11 is included in the charge detection circuit 25 and amplifies the voltage applied to the gate electrode. The address transistor 13 selectively reads out the amplified voltage as a signal voltage. The address transistor 13 is also referred to as a row selection transistor. The reset transistor 12 has a source electrode and a drain electrode one of which is connected to the pixel electrode 61 and resets the signal charge stored in the charge storage node 24. That is, the reset transistor 12 resets the potential of the gate electrode of the amplifier transistor 11 and the potential of the pixel electrode 61.

To selectively perform the operations described above in the plurality of sub-pixels 111 or 112, the imaging device 100 includes a power supply line 21, a vertical signal line 17, an address signal line 26, and a reset signal line 27. Each of the line and signal lines is connected to the sub-pixels 111 or 112.

More specifically, the power supply line 21 is connected to one of the source electrode and drain electrode of the amplifier transistor 11. The other of the source electrode and drain electrode of the amplifier transistor 11 is connected to one of the source electrode and drain electrode of the address transistor 13. The vertical signal line 17 is connected to the other of the source and drain electrodes of the address transistor 13, that is, the electrode not connected to the amplifier transistor 11. The address signal line 26 is connected to the gate electrode of the address transistor 13. The reset signal line 27 is connected to the gate electrode of the reset transistor 12.

The peripheral circuit 120 includes a vertical scanning circuit 15, a horizontal signal readout circuit 20, a plurality of column signal processing circuits 19, a plurality of load circuits 18, a plurality of differential amplifiers 22, and the voltage control circuit 30. The vertical scanning circuit 15 is also referred to as a row scanning circuit. The horizontal signal readout circuit 20 is also referred to as a column scanning circuit. The column signal processing circuit 19 is also referred to as the row signal storage circuit. The differential amplifier 22 is also referred to as a feedback amplifier.

The vertical scanning circuit 15 is connected to the address signal line 26 and the reset signal line 27 and selects the plurality of sub-pixels 111 or 112 arranged in each row on a row basis to read out the signal voltage and reset the potential of the pixel electrode 51 or 61. The power supply line 21 supplies a predetermined power supply voltage to each of the sub-pixels 111 and 112. The horizontal signal readout circuit 20 is electrically connected to the plurality of column signal processing circuits 19. The column signal processing circuits 19 are each electrically connected to the sub-pixels 111 and 112 located in each column via the vertical signal line 17 corresponding to the column. Each of the load circuits 18 is electrically connected to one of the vertical signal lines 17. The load circuit 18 and the amplifier transistor 11 form a source follower circuit.

The plurality of differential amplifiers 22 are provided in one-to-one correspondence to the rows. The negative input terminal of the differential amplifier 22 is connected to the corresponding one of the vertical signal lines 17. The output terminal of the differential amplifier 22 is connected to the sub-pixel 111 or 112 via the feedback line 23 corresponding to one of the columns.

The vertical scanning circuit 15 applies a row selection signal that controls on and off of the address transistor 13 to the gate electrodes of the address transistors 13 by using the address signal line 26. As a result, the row to be read out is scanned and selected. The signal voltage is read out from the sub-pixel 111 or 112 in the selected row to the vertical signal line 17. Alternatively, the vertical scanning circuit 15 applies a reset signal that controls on and off of the reset transistor 12 to the gate electrodes of the reset transistors 12 via the reset signal line 27. Thus, the row of the sub-pixels 111 or 112 subject to a reset operation is selected. The vertical signal line 17 transmits the signal voltage read out from the sub-pixel 111 or 112 selected by the vertical scanning circuit 15 to the column signal processing circuit 19.

The column signal processing circuit 19 performs noise reduction signal processing, analog-to-digital conversion (AD conversion), and the like, as typified by correlated double sampling. More specifically, the column signal processing circuit 19 includes a sample-and-hold circuit. The sample-and-hold circuit includes a capacitor and a transistor. The sample-and-hold circuit samples and temporarily holds the signal voltage read out via the vertical signal line 17. A digital value corresponding to the held voltage value is read out by the horizontal signal readout circuit 20.

The horizontal signal readout circuit 20 sequentially reads signals from the plurality of column signal processing circuits 19 to the horizontal common signal line 28.

The differential amplifier 22 is connected to the other of the drain electrode and the source electrode of the reset transistor 12 (that is, the electrode not connected to the pixel electrode 51 or 61) via the feedback line 23. Thus, the negative input terminal of the differential amplifier 22 receives the output value of the address transistor 13 when the address transistor 13 and the reset transistor 12 are in a conducting state. The differential amplifier 22 performs a feedback operation so that the gate potential of the amplifier transistor 11 becomes the predetermined feedback voltage. At this time, the output voltage value of the differential amplifier 22 is 0 V or a positive voltage close to 0 V. The term “feedback voltage” refers to the output voltage of the differential amplifier 22.

### 2. Pixel Structure

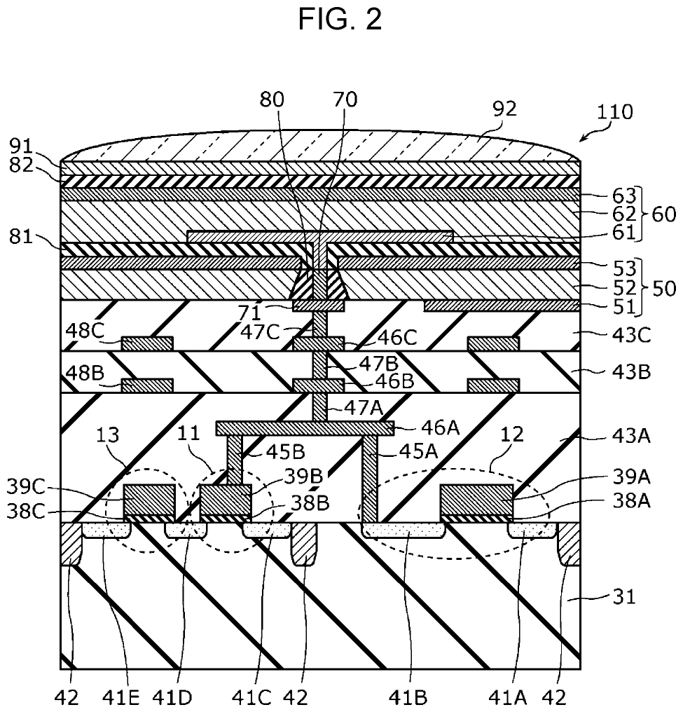

The device structure of the pixel 110 of the imaging device 100 is described in detail below with reference to FIG. 2. FIG. 2 is a schematic cross-sectional view of the device structure of the pixel 110 of the imaging device 100.

As illustrated in FIG. 2, the pixel 110 includes a semiconductor substrate 31, the charge detection circuit 25 (not illustrated), and the photoelectric converters 50 and 60. The semiconductor substrate 31 is, for example, a p-type silicon substrate. The charge detection circuit 25 detects the signal charge captured by the pixel electrode 51 or 61 and outputs a signal voltage. The charge detection circuit 25 includes the amplifier transistor 11, the reset transistor 12, and the address transistor 13. At least a subset of the charge detection circuit 25 is formed on the semiconductor substrate 31.

Each of the amplifier transistor 11, the reset transistor 12, and the address transistor 13 is an example of an electrical element at least subset of which is formed on the semiconductor substrate 31. Each of the amplifier transistor 11, the reset transistor 12, and the address transistor 13 is, for example, a MOSFET (Metal Oxide Semiconductor Field Effect Transistor). More specifically, each of the amplifier transistor 11, the reset transistor 12, and the address transistor 13 is an n-channel MOSFET but may be a p-channel MOSFET.

The amplifier transistor 11 has n-type impurity regions 41C and 41D, a gate insulating layer 38B, and a gate electrode 39B. Each of the n-type impurity regions 41C and 41D is formed in the semiconductor substrate 31 and serves as a drain or source. The gate insulating layer 38B is located on semiconductor substrate 31. The gate electrode 39B is located on the gate insulating layer 38B.

The reset transistor 12 has n-type impurity regions 41A and 41B, a gate insulating layer 38A, and a gate electrode 39A. Each of the n-type impurity regions 41A and 41B is formed in the semiconductor substrate 31 and serves as a drain or source. The gate insulating layer 38A is located on semiconductor substrate 31. The gate electrode 39A is located on the gate insulating layer 38A.

The address transistor 13 has n-type impurity regions 41D and 41E, a gate insulating layer 38C, and a gate electrode 39C. Each of the n-type impurity regions 41D and 41E is formed in the semiconductor substrate 31 and serves as a drain or source. The gate insulating layer 38C is located on semiconductor substrate 31. The gate electrode 39C is located on the gate insulating layer 38C.

The gate insulating layers 38A, 38B, and 38C are formed using an insulating material. For example, the gate insulating layers 38A, 38B and 38C have a single-layer structure of a silicon oxide film or silicon nitride film or a stacked structure of these films.

The gate electrodes 39A, 39B, and 39C are each formed using a conductive material. For example, the gate electrodes 39A, 39B, and 39C are formed using polysilicon having conductivity due to added impurities. Alternatively, the gate electrodes 39A, 39B, and 39C may be formed using a metallic material, such as copper.

The n-type impurity regions 41A, 41B, 41C, 41D, and 41E are formed by doping n-type impurities, such as phosphorus (P), into the semiconductor substrate 31 by, for example, ion implantation. In the example illustrated in FIG. 2, the n-type impurity region 41D is shared by the amplifier transistor 11 and the address transistor 13. As a result, the amplifier transistor 11 and the address transistor 13 are connected in series. The n-type impurity region 41D may be separated into two n-type impurity regions. The two n-type impurity regions may be electrically connected via a wiring layer.

In the semiconductor substrate 31, an element separation region 42 is provided between adjacent pixels 110 and between the amplifier transistor 11 and the reset transistor 12. The element separation region 42 electrically separates the adjacent pixels 110. In addition, the presence of the element separation region 42 prevents leakage of signal charge stored in the charge storage node 24. The element separation region 42 is formed by, for example, doping a high concentration of p-type impurities in the semiconductor substrate 31.

A multilayer wiring structure is provided on the upper surface of the semiconductor substrate 31. The multilayer wiring structure includes a plurality of interlayer insulating layers, one or more wiring layers, one or more vias, and one or more contact plugs. More specifically, interlayer insulating layers 43A, 43B, and 43C are stacked in this order on the upper surface of semiconductor substrate 31. The interlayer insulating layers 43A, 43B and 43C are, for example, TEOS (tetraethyl orthosilicate) films, but may be single or multilayer films, such as silicon oxide films, silicon nitride films, silicon oxynitride films, and aluminum oxide films. The interlayer insulating layers 43A, 43B and 43C may be formed using the same insulating material or using different insulating materials from one another.

The interlayer insulating layer 43A has, embedded therein, contact plugs 45A and 45B, a wiring line 46A, and a via 47A. The interlayer insulating layer 43B has a wiring lines 46B and 48B and a via 47B embedded therein. The interlayer insulating layer 43C has wiring lines 46C and 48C, a via 47C, the pixel electrode 51, and a conductive film 71 embedded therein. The upper surface of the interlayer insulating layer 43C is, for example, flat and is parallel to the upper surface of the semiconductor substrate 31.

The contact plug 45A is connected to the n-type impurity region 41B of the reset transistor 12. The contact plug 45B is connected to the gate electrode 39B of the amplifier transistor 11. The wiring line 46A connects the contact plug 45A to the contact plug 45B. As a result, the n-type impurity region 41B of the reset transistor 12 is electrically connected to the gate electrode 39B of the amplifier transistor 11.

The wiring line 46A is connected to the pixel electrode 61 via the vias 47A, 47B and 47C, the wiring lines 46B and 46C, the conductive film 71, and a plug 70. As a result, the n-type impurity region 41B, gate electrode 39B, contact plugs 45A and 45B, wiring lines 46A, 46B and 46C, vias 47A, 47B and 47C, conductive film 71, plug 70, and pixel electrode 61 constitute the charge storage node 24.

Although not illustrated in FIG. 2, the vias and wiring lines connected to the pixel electrode 51 are also embedded in the interlayer insulating layers 43A, 43B or 43C. The amplifier transistor 11, reset transistor 12, and address transistor 13 included in the sub-pixel 111 are also formed in the semiconductor substrate 31.

The photoelectric converters 50 and 60 are each located above the semiconductor substrate 31. The photoelectric converters 50 and 60 are stacked in this order above the semiconductor substrate 31.

The photoelectric converter 50 is an example of a first photoelectric converter that converts light having a wavelength in the first wavelength range into first charge. The photoelectric converter 50 is provided on the interlayer insulating layer 43C.

The photoelectric converter 60 is located above the photoelectric converter 50 and is an example of a second photoelectric converter that converts light having a wavelength in the second wavelength range into second charge. The photoelectric converter 60 is provided above the photoelectric converter 50 with the insulating layer 81 therebetween.

The first wavelength range and the second wavelength range are different wavelength ranges from each other. More specifically, the first wavelength range and the second wavelength range are different wavelength ranges without any overlap at all but may partially overlap. For example, the light having a wavelength in the first wavelength range is near-infrared light. For example, the light having a wavelength in the second wavelength range is visible light. Particular structures of the photoelectric converters 50 and 60 are described below.

An insulating layer 82 is provided above the photoelectric converter 60. The insulating layer 82 covers at least part of the upper surface of the transparent electrode 63.

The insulating layer 82 is formed using an insulating material. For example, the insulating layer 82 is formed of silicon oxide (SiO₂), silicon nitride (SiN), silicon oxynitride (SiON), aluminum oxide (AlO), or an organic or inorganic polymer material. The insulating layer 82 is transparent, for example, to light of the wavelengths to be detected by the imaging device 100 and, more specifically, light having a wavelength in the first wavelength range and light having a wavelength in the second wavelength range. The insulating layer 82 functions as a protective film for the photoelectric converter 60.

As illustrated in FIG. 2, the pixel 110 includes a color filter 91 above the photoelectric converter 60. Furthermore, the pixel 110 includes a microlens 92 above the color filter 91. Note that the pixel 110 need not include the insulating layer 82, the color filter 91, and the microlens 92.

### 3. Photoelectric Converter

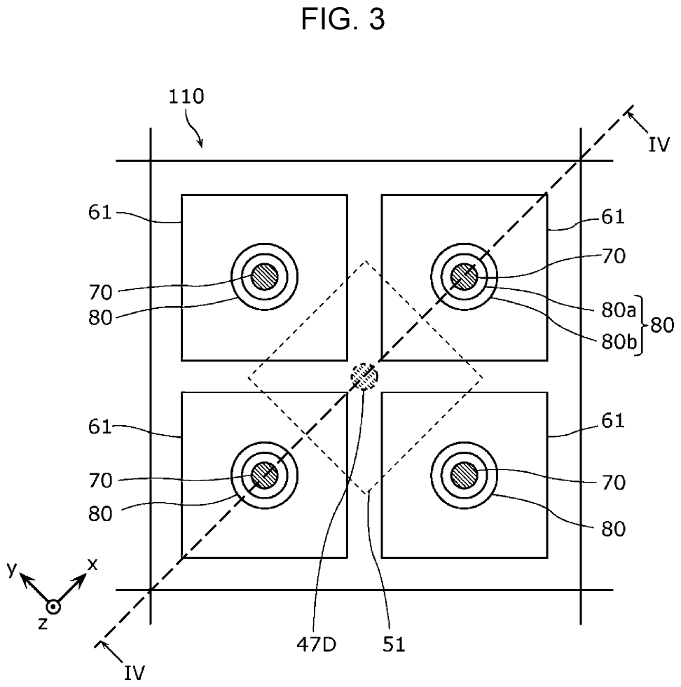

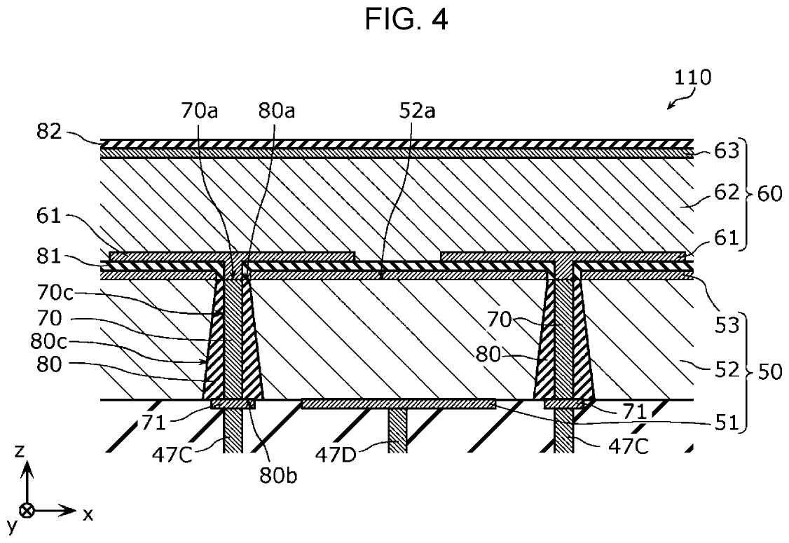

The structures of the two photoelectric converters 50 and 60 according to the present embodiment are described below with reference to FIGS. 3 and 4.

FIG. 3 is a plan view illustrating the electrode layout of the pixel 110 of the imaging device 100 according to the present embodiment. FIG. 4 is a schematic cross-sectional view of the photoelectric converters 50 and 60 of the pixel 110 taken along line IV-IV of FIG. 3.

As illustrated in FIGS. 2 and 4, the photoelectric converter 50 includes the pixel electrode 51, the photoelectric conversion layer 52, and the transparent electrode 53.

The pixel electrode 51 is an example of a first pixel electrode. The pixel electrode 51 faces the transparent electrode 53 with the photoelectric conversion layer 52 therebetween. The pixel electrode 51 is provided in each of the pixels 110. According to the present embodiment, as illustrated in FIG. 3, one pixel electrode 51 is provided in one pixel 110. However, a plurality of pixel electrodes 51 may be provided in one pixel 110. The pixel electrode 51 is formed of a metal, such as aluminum or copper, or a conductive material, such as polysilicon having conductivity due to doped impurities.

The pixel electrode 51 is connected to a charge storage region (not illustrated) provided below. More specifically, as illustrated in FIG. 4, a via 47D is connected to the lower surface of pixel electrode 51. The via 47D is electrically connected to an impurity region (also referred to as “floating diffusion”) provided in the semiconductor substrate 31 via a wiring line, another via, a contact plug, and the like (neither is illustrated). However, the via 47D may be directly connected to the impurity region. Each of the via 47D and the impurity region is part of the charge storage region. As a result, charge generated through photoelectric conversion in the photoelectric conversion layer 52 is stored in the charge storage region via the pixel electrode 51.

The photoelectric conversion layer 52 is an example of a first photoelectric conversion layer. The photoelectric conversion layer 52 photoelectrically converts light incident from the side with the transparent electrode 53 and generates signal charge corresponding to the intensity of the incident light. More specifically, the photoelectric conversion layer 52 receives near-infrared light and generates signal charge in accordance with the intensity of the received near-infrared light.

The photoelectric conversion layer 52 contains an organic substance. For example, the photoelectric conversion layer 52 is composed of an organic semiconductor. The photoelectric conversion layer 52 may include one or more organic semiconductor layers. For example, the photoelectric conversion layer 52 may include, in addition to a photoelectric conversion layer that generates hole-electron pairs, a carrier transport layer that transports electrons or holes and a blocking layer that blocks carriers. An organic p-type or organic n-type semiconductor of a well-known material can be used for the organic semiconductor layer.

The photoelectric conversion layer 52 may be, for example, a mixed film of organic donor molecules and acceptor molecules, a mixed film of semiconducting carbon nanotubes and acceptor molecules, or a film containing quantum dots. The photoelectric conversion layer 52 may be formed using an inorganic material, such as amorphous silicon.

The photoelectric conversion layer 52 is located between the pixel electrode 51 and the transparent electrode 53. According to the present embodiment, the photoelectric conversion layer 52 is continuously formed over a plurality of pixels 110. More specifically, the photoelectric conversion layer 52 is formed as a single flat plate so as to cover most of the imaging region in plan view. The photoelectric conversion layer 52 may be provided separately for each of the pixels 110.

The transparent electrode 53 is an example of a first counter electrode and is located above the pixel electrode 51. The transparent electrode 53 is translucent to light having a wavelength in the first wavelength range to be detected by the photoelectric conversion layer 52. More specifically, the transparent electrode 53 is transparent to light having a wavelength in the first wavelength range. The term “transparent” refers to a state in which the transmittance to light having a wavelength in a given wavelength range is sufficiently high. For example, the term “transparent” refers to a state in which the transmittance to light having a wavelength in a given wavelength range is greater than 50%.

The transparent electrode 53 is formed using a conductive material. For example, the transparent electrode 53 is formed using a transparent conductive semiconductor oxide film, such as an indium tin oxide (ITO), aluminum-doped zinc oxide (AZO), or gallium-doped zinc oxide (GZO) film. The transparent electrode 53 may be formed using another transparent conductive semiconductor or a thin metal film thin enough to transmit light having a wavelength in the first wavelength range.

Like the photoelectric conversion layer 52, the transparent electrode 53 is formed continuously over a plurality of pixels 110. More specifically, the transparent electrode 53 is formed as a single flat plate so as to cover most of the imaging region in plan view. The transparent electrode 53 continuously covers almost the entire upper surface of the photoelectric conversion layer 52.

As illustrated in FIGS. 2 and 4, the photoelectric converter 60 includes the pixel electrode 61, the photoelectric conversion layer 62, and the transparent electrode 63.

The pixel electrode 61 is an example of a second pixel electrode. The pixel electrode 61 faces the transparent electrode 63 with the photoelectric conversion layer 62 therebetween. The pixel electrode 61 is provided for each of the pixels 110. According to the present embodiment, as illustrated in FIG. 3, four pixel electrodes 61 are provided in one pixel 110. However, the four pixel electrodes 61 may be connected to each other to form a single pixel electrode.

The photoelectric conversion layer 62 is an example of a second photoelectric conversion layer. The photoelectric conversion layer 62 photoelectrically converts light incident from the side with the transparent electrode 63 to generate signal charge corresponding to the intensity of the incident light. More specifically, the photoelectric conversion layer 62 receives visible light and generates signal charge corresponding to the intensity of the received visible light.

The photoelectric conversion layer 62 contains an organic substance. For example, the photoelectric conversion layer 62 is composed of an organic semiconductor. The photoelectric conversion layer 62 may include one or more organic semiconductor layers. The photoelectric conversion layer 62 may include a carrier transport layer and a blocking layer.

The photoelectric conversion layer 62 may be, for example, a mixed film of organic donor molecules and acceptor molecules, a mixed film of semiconducting carbon nanotubes and acceptor molecules, or a film containing quantum dots. The photoelectric conversion layer 62 may be formed using an inorganic material, such as amorphous silicon.

The photoelectric conversion layer 62 is located between the pixel electrode 61 and the transparent electrode 63. According to the present embodiment, the photoelectric conversion layer 62 is continuously formed over the plurality of pixels 110. The photoelectric conversion layer 62 may be provided separately for each of the pixels 110.

The transparent electrode 63 is an example of a second counter electrode and is located above the pixel electrode 61. The transparent electrode 63 is translucent to light having a wavelength in the second wavelength range to be detected by the photoelectric conversion layer 62. More specifically, the transparent electrode 63 is transparent to light having a wavelength in the second wavelength range.

The transparent electrode 63 is formed using a conductive material. For example, the transparent electrode 63 is formed using a transparent conductive semiconductor oxide film, such as an ITO, AZO, or GZO film. The transparent electrode 63 may be formed using another transparent conductive semiconductor or a thin metal film thin enough to transmit light.

The photoelectric converter 60 is located at the side on which the light having a wavelength in the first wavelength range that is received by the photoelectric converter 50 is incident. Therefore, the pixel electrode 61, the photoelectric conversion layer 62, and the transparent electrode 63, all of which constitute the photoelectric converter 60, are translucent to light having a wavelength in the first wavelength range. More specifically, the pixel electrode 61, the photoelectric conversion layer 62, and the transparent electrode 63 are all transparent to light having a wavelength in the first wavelength range.

An insulating layer 81 is provided between the photoelectric converter 50 and the photoelectric converter 60. The insulating layer 81 is provided to electrically insulate the photoelectric converter 50 from the photoelectric converter 60. Since the photoelectric converter 50 is disposed below the photoelectric converter 60, the insulating layer 81 is also formed using a material that transmits light having a wavelength in the first wavelength range to be received by the photoelectric converter 50. More specifically, the insulating layer 81 is formed using AlO, SiON, or the like.

The pixel electrode 61 of the photoelectric converter 60 is connected to the plug 70 that is conductive and that penetrates through the photoelectric conversion layer 52. The pixel electrode 61 is connected, through the plug 70, to the conductive film 71 formed below the photoelectric conversion layer 52 and is further connected to a charge storage region for storing the charge generated during photoelectric conversion. For example, as illustrated in FIG. 2, the pixel electrode 61 is connected to the n-type impurity region 41B via the plug 70, the conductive film 71, the via 47C, and the like. The n-type impurity region 41B is part of the charge storage region.

The plug 70 is formed using a metallic material, such as Cu. The plug 70 is, for example, a cylindrical plug and has a height substantially the same as the thickness of the photoelectric conversion layer 52. An insulating layer 80 is provided around the plug 70 to electrically insulate the plug 70 from the photoelectric conversion layer 52.

The insulating layer 80 is located between the plug 70 and the photoelectric conversion layer 52 and covers a side surface 70c of the plug 70. The insulating layer 80 is formed using an insulating material, such as TEOS, SiO₂ or SiN.

The insulating layer 80 has a tapered shape that tapers upward. More specifically, the shape of the insulating layer 80 is a conical trapezoidal shape having a through-hole at the center. As illustrated in FIGS. 3 and 4, the plug 70 is embedded in the through-hole at the center. The insulating layer 80 has an upper surface 80a and a lower surface 80b. The area of the upper surface 80a is less than that of the lower surface 80b. More specifically, the inner circumference of the upper surface 80a and the inner circumference of the lower surface 80b overlap each other and match the outer shape of the plug 70 in plan view. The outer circumference of the upper surface 80a is located on an inner side of the outer circumference of the lower surface 80b. The lower surface 80b is larger than the conductive film 71, thus preventing the conductive film 71 from contacting the photoelectric conversion layer 52.

The inclination angle of an outer side surface 80c of the insulating layer 80 is constant. The inclination angle is the angle formed by the outer side surface 80c and the xy plane in the xz cross-section that passes through the center of the plug 70 (that is, the cross-section illustrated in FIG. 4). The xy plane is parallel to the principal surface of the semiconductor substrate 31.

For example, the shape of the insulating layer 80 is not limited to a conical trapezoidal shape having a through-hole at the center. For example, the outer side surface 80c of the insulating layer 80 may be convexly curved downward or upward. That is, the inclination of the outer side surface 80c of the insulating layer 80 need not be constant. Alternatively, the outer side surface 80c of the insulating layer 80 may be formed in a staircase shape.

### 4. Manufacturing Method

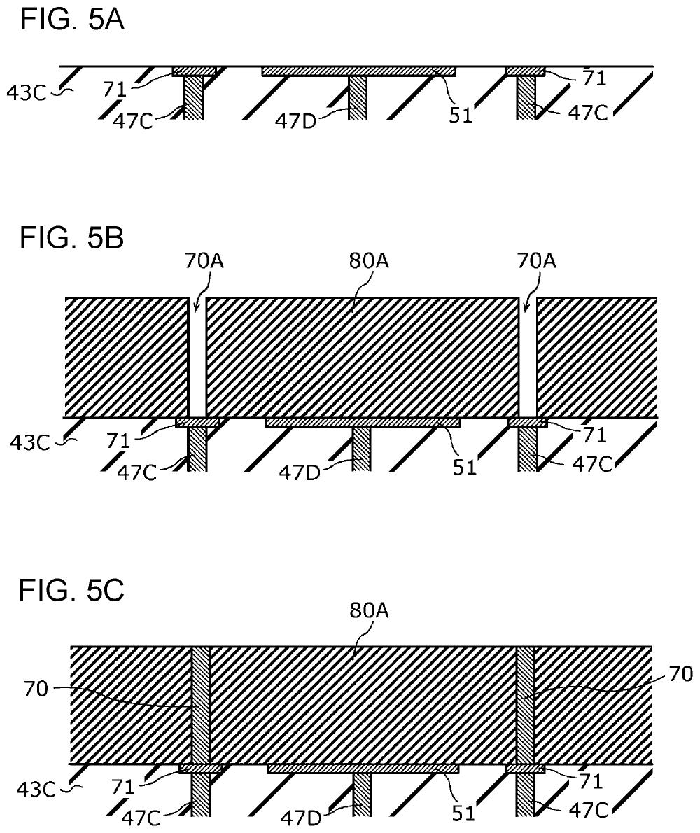

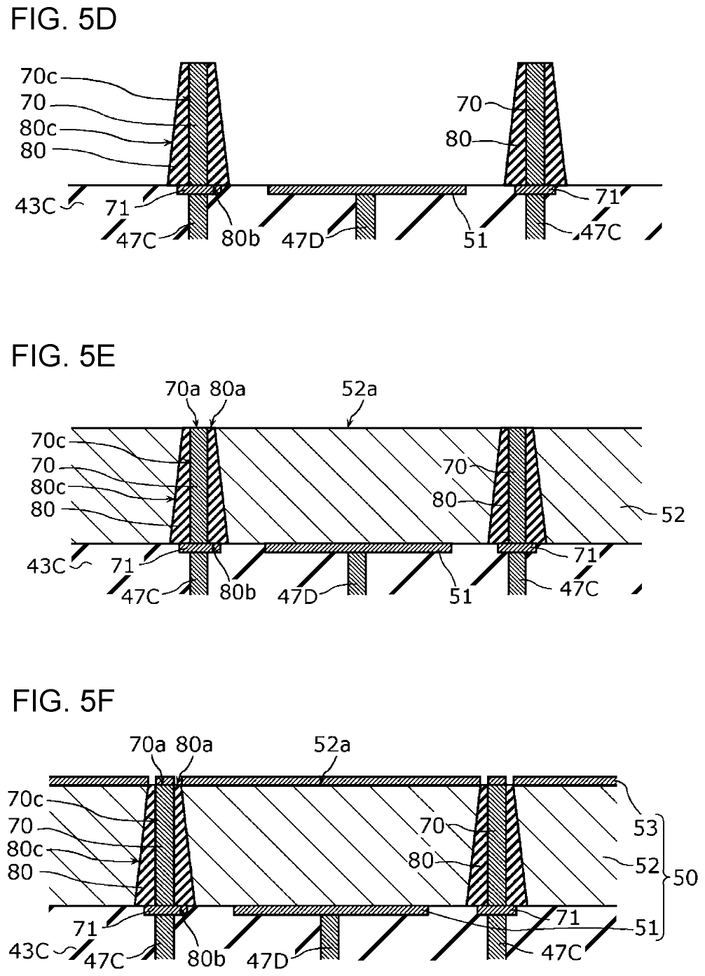

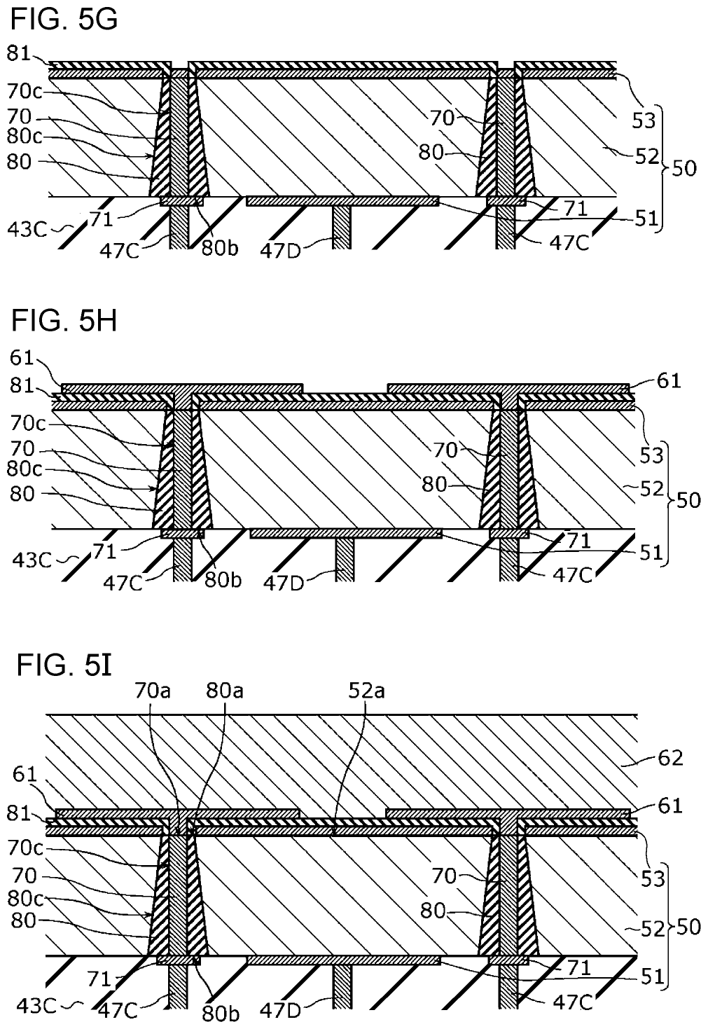

A method for manufacturing the stacked structure of the photoelectric converter illustrated in FIG. 4 is described with reference to FIGS. 5A to 5I. FIGS. 5A to 5I are cross-sectional views illustrating the processes of the method for manufacturing the imaging device.

As illustrated in FIG. 2, the charge detection circuit 25 is formed first inside the semiconductor substrate 31. More specifically, the amplifier transistor 11, the reset transistor 12, the address transistor 13, and the element separation region 42 are formed using a well-known technique, such as CMOS process.

Subsequently, a plurality of interlayer insulating layers 43A, 43B, and 43C, and the wiring lines and vias in the interlayer insulating layers are formed so as to cover the upper surface of the semiconductor substrate 31. FIG. 5A illustrates the uppermost interlayer insulating layer 43C and the vias 47C and 47D, the pixel electrode 51, and the conductive films 71 provided inside the interlayer insulating layer 43C. Hatchings indicating a cross section is omitted in the interlayer insulating layer 43C. In addition, the semiconductor substrate 31 and the like are not illustrated in FIGS. 5A to 5I.

The interlayer insulating layer 43C is a TEOS film, for example, and is formed by a CVD (Chemical Vapor Deposition) technique or the like. Contact holes are formed in the TEOS film by photolithography and etching, and Cu is embedded in the contact holes to form the vias 47C and 47D. Furthermore, embedded TiN electrodes are formed in the upper layer portion of the TEOS film as the conductive films 71 and pixel electrode 51.

Subsequently, as illustrated in FIG. 5B, after the TEOS film 80A is deposited over the entire region, a portion corresponding to the lower portion of the pixel electrode 61 of the photoelectric converter 60, that is, the portion immediately above the conductive film 71 is removed by etching to form a via hole 70A. As a result, the upper surface of the conductive film 71 is exposed at the bottom of the via hole 70A.

Subsequently, the plug 70 is formed by embedding Cu in the via hole 70A, as illustrated in FIG. 5C. The Cu embedding is done using electrolytic plating, for example. Therefore, although not illustrated, a seed layer used for plating and a barrier layer used to prevent Cu diffusion are formed on the bottom surface and the side surface of the plug 70 made of Cu. For the barrier layer, Ti or Ta is used, for example.

Subsequently, as illustrated in FIG. 5D, dry etching, for example, is performed to remove the TEOS film 80A except a portion of the TEOS film 80A in the vicinity of the plug 70. At this time, the etching conditions are controlled so that the width of the TEOS film covering the side surface 70c of the plug 70 increases from the top toward the bottom of the plug 70. This allows the shape of the insulating layer 80, which is the remaining TEOS film, to taper upward.

To achieve the anisotropy in etching, the etching gas is mixed with a gas that causes reaction products to adhere to the sidewall of the etched portion, in general. For example, the shape of the insulating layer 80 formed by etching can be controlled by adjusting the mixing ratio of the gases. Alternatively, the shape of the insulating layer 80 can be controlled by selecting a resist, which is a protective material during etching. That is, by using a resist that has a property of being easily inclined at the edge, the tapered shape of the insulating layer 80 can be formed. That is, the outer side surface 80c of the insulating layer 80 is inclined diagonally.

Subsequently, as illustrated in FIG. 5E, the interlayer insulating layer 43C is coated with a photoelectric conversion material, which is the primary material of the photoelectric conversion layer 52, by spin coating. At this time, since the areas of the upper surfaces of the plug 70 and the insulating layer 80 are relatively small, the probability is low that the coating film formed by spin coating moves onto the upper surfaces of the plug 70 and the insulating layer 80. In addition, due to the re-flow of the coating material that occurs immediately after coating until complete drying of the coating material, the coating film on the top of the plug 70 and on the top of the insulating layer 80 slides down to the surrounding area via the inclined outer side surface 80c of the insulating layer 80. As a result, as illustrated in FIG. 5E, an upper surface 70a of the plug 70, the upper surface 80a of the insulating layer 80, and the upper surface 52a of the photoelectric conversion layer 52 can be made flush. To make the height of the coating film the same as that of the plug 70, another process may be separately performed to optimize a variety of parameters, such as the rotational speed of the spin coating or the viscosity of the coating material.

Subsequently, as illustrated in FIG. 5F, an electrode material is deposited on the upper surface 52a of the photoelectric conversion layer 52, the upper surface 70a of the plug 70, and the upper surface 80a of the insulating layer 80. Deposition of the electrode material film is performed by, for example, sputtering or vapor deposition. Furthermore, the electrode material on the upper surface 80a of the insulating layer 80 is removed by patterning the formed electrode material film. This process separates the electrode material on the top of the photoelectric conversion layer 52 from the electrode material on the top of the plug 70. The electrode material on the top of the photoelectric conversion layer 52 is the transparent electrode 53 of the photoelectric converter 50.

Subsequently, as illustrated in FIG. 5G, an insulating film is deposited over the entire surface, and only the insulating film on the upper portion of the plug 70 is removed by etching. As a result, the insulating layer 81 is formed so that only the electrode material to be electrically connected to the plug 70 is exposed.

Subsequently, as illustrated in FIG. 5H, the electrode material is deposited on the upper surface of the insulating layer 81 and is patterned into a predetermined shape by etching. This forms the pixel electrode 61 of the photoelectric converter 60.

Subsequently, as illustrated in FIG. 5I, the photoelectric conversion layer 62 is formed. Like the photoelectric conversion layer 52, the photoelectric conversion layer 62 is formed by, for example, spin coating.

Subsequently, the transparent electrode 63 is formed on top of the photoelectric conversion layer 62, and the insulating layer 82 is formed as a protective film on the upper surface of the transparent electrode 63. This forms the stacked structure of photoelectric converters 50 and 60 illustrated in FIG. 4. If necessary, the color filter 91 and the microlens 92 are formed. Thus, the imaging device 100 illustrated in FIG. 2 is produced.

According to the above-described manufacturing method, when the photoelectric conversion layer 52 is formed, it is not necessary to perform planarization processes, such as etch-back by oxygen plasma or mechanical polishing by CMP. This can reduce the probability of degradation of the characteristics of the photoelectric conversion layer 52 and degradation of the strength of the film interface.

### 5. Modifications

Modifications of the embodiment are described below.

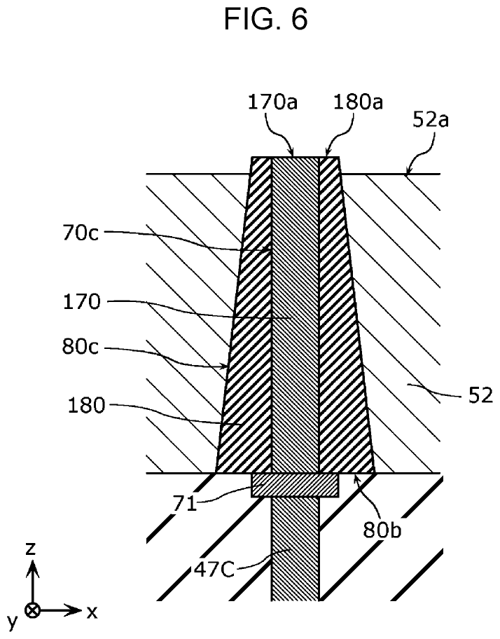

FIG. 6 is a cross-sectional view of a plug 170 penetrating through the photoelectric conversion layer 52 of an imaging device according to Modification 1. As illustrated in FIG. 6, an upper surface 170a of the plug 170 and an upper surface 180a of an insulating layer 180 are located above the upper surface 52a of the photoelectric conversion layer 52. That is, the upper surface 170a of the plug 170 and the upper surface 180a of the insulating layer 180 need not be flush with the upper surface 52a of the photoelectric conversion layer 52. This facilitates the manufacturing of the imaging device 100 because strict accuracy is not required in the process of optimizing parameters, such as the rotational speed of the spin coating or the viscosity of the coating material, related to formation of the photoelectric conversion layer 52 and, thus, a certain level of variation can be tolerated.

In FIG. 6, an example is illustrated in which the upper surface 170a of the plug 170 and the upper surface 180a of the insulating layer 180 are flush. However, there may be a difference in level between the upper surface 170a and the upper surface 180a. For example, the upper surface 170a of the plug 170 may be at a higher level than the upper surface 180a of the insulating layer 180.

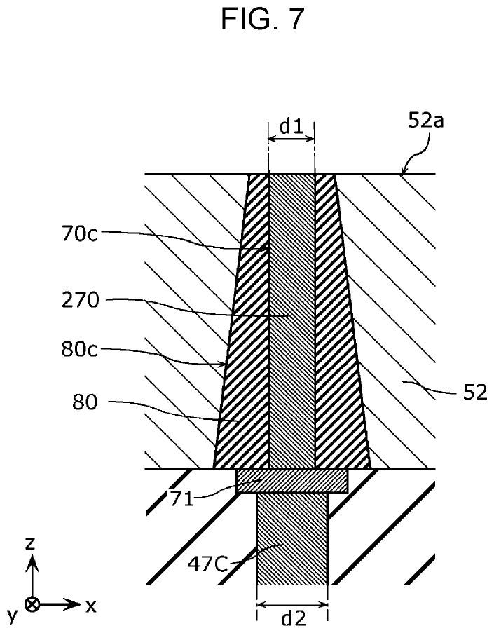

FIG. 7 is a cross-sectional view of a plug 270 penetrating through the photoelectric conversion layer 52 of an imaging device according to Modification 2. As illustrated in FIG. 7, a width d1 of the plug 270 is less than a width d2 of the via 47C to which the plug 270 is connected. The widths d1 and d2 are the largest widths of the plug 270 and the via 47C, respectively. If the plug 270 is columnar in shape, the width d1 is the diameter of the bottom surface. For example, the entirety of plug 270 is located inside of the outer contour of the via 47C in plan view.

Thus, the areas of the upper surface 70a of the plug 270 and the upper surface 80a of the insulating layer 80 further decrease with decreasing thickness of the plug 270. This makes it easier to planarize the photoelectric conversion layer 52 because the coating film is less likely to remain on the upper surface 70a of the plug 270 and the upper surface 80a of the insulating layer 80.

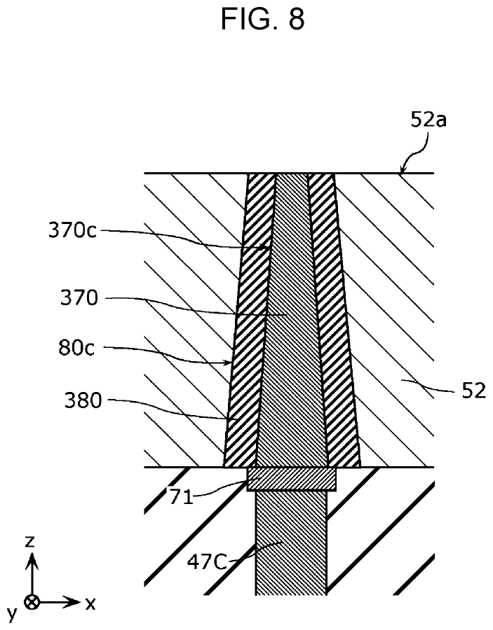

FIG. 8 is a cross-sectional view of a plug 370 penetrating through the photoelectric conversion layer 52 of an imaging device according to Modification 3. As illustrated in FIG. 8, the plug 370 has a tapered shape that tapers upward. That is, a side surface 370c of the plug 370 is inclined with respect to the xy plane. The shape of the plug 370 is, for example, an upwardly tapering cone or pyramid.

According to the present modification, the width of an insulating layer 380 is constant. That is, in a cross-section perpendicular to the xy plane, the outer side surface 80c of the insulating layer 380 and the side surface 370c of the plug 370 are parallel to each other. As described above, the plug 370 may have a tapered shape and, thus, the insulating layer 380 covering the side surface 370c of the plug 370 may have a tapered shape that tapers upward. Even in this case, the same effect as in the above-described embodiment can be obtained.

The width of the insulating layer 380 does not have to be constant. For example, the thickness of the insulating layer 380 may be greater at the bottom than at the top. In this case, the tapered shape of the insulating layer 380 has a smaller inclination angle than the tapered shape of the plug 370. Alternatively, the thickness of the insulating layer 380 may be greater at the bottom end than at the top end as long as the outer side surface 80c of the insulating layer 380 is inclined so as to taper upward.

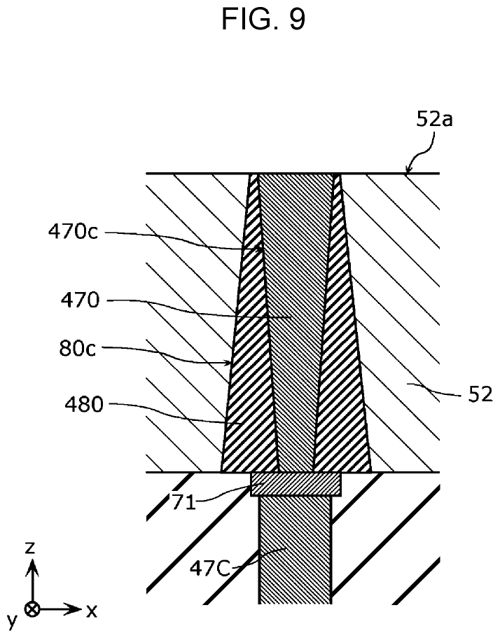

FIG. 9 is a cross-sectional view of a plug 470 penetrating through the photoelectric conversion layer 52 of an imaging device according to Modification 4. As illustrated in FIG. 9, the plug 470 has a tapered shape that tapers downward, that is, an inverse tapered shape. That is, as compared with the side surface 370c illustrated in FIG. 8, a side surface 470c of the plug 470 is inclined toward the opposite side with respect to the z-axis direction. The shape of the plug 470 is, for example, a downwardly tapering cone or pyramid.

According to the present modification, the width of the insulating layer 480 is greater at the bottom end than at the top end. The insulating layer 480 is provided to fill the space between the plug 470 and the conductive film 71, and the outer side surface 80c is inclined so as to taper upward. Even in this case, the same effect as in the above-described embodiment can be obtained.

The shape of the plug and the insulating layer according to each of the modifications can be formed by adjusting the etching and deposition conditions as appropriate.

### Other Embodiments

While the above description has been made with reference to the imaging device according to at least one aspect, the present disclosure is not limited thereto. A variety of modifications of the present embodiment that are conceivable by those skilled in the art and embodiments configured by combining the constituent elements of different embodiments may be encompassed in the scope of the present disclosure without departing from the spirit and scope of the present disclosure.

For example, according to the above-described embodiment, the photoelectric converter 50 located adjacent to the semiconductor substrate 31 receives near-infrared light, and the photoelectric converter 60 located above receives visible light. However, the configuration is not limited thereto. The photoelectric converter 60 may receive near-infrared light, and the photoelectric converter 50 may receive visible light. Alternatively, the photoelectric converters 50 and 60 may each receive light having a wavelength in a different wavelength range, such as different visible light.

The photoelectric converters 50 and 60 may receive light having a wavelength in the same wavelength range. That is, the first wavelength range and the second wavelength range may be exactly the same. The range of light that can be received in the same wavelength range is expanded, and the dynamic range of the imaging device can be increased.

For example, three or more photoelectric converters may be stacked. The wavelength ranges of the light detected by the three photoelectric converters may overlap at least partially or may be completely different.

For example, in the photoelectric converter 60, the arrangement of the pixel electrode 61 and the transparent electrode 63 may be reversed. That is, the transparent electrode 63, the photoelectric conversion layer 62, and the pixel electrode 61 may be arranged in this order from the photoelectric converter 50. In this case, the transparent electrode 53 of the photoelectric converter 50 and the transparent electrode 63 of the photoelectric converter 60 may be one common electrode. The plug 70 and the insulating layer 80 may penetrate through the photoelectric conversion layer 62. In this case, the insulating layer 80 has a tapered shape that tapers upward at the portion located between the plug 70 and the photoelectric conversion layer 52 and at the portion located between the plug 70 and the photoelectric conversion layer 62. That is, the insulating layer 80 has, for example, two conical portions.

For example, in the photoelectric converter 50, the arrangement of the pixel electrode 51 and the transparent electrode 53 may be reversed. That is, the transparent electrode 53, the photoelectric conversion layer 52, and the pixel electrode 51 may be arranged in this order from the semiconductor substrate 31.

A variety of changes, substitutions, additions, and deletions can be made in each of the above embodiments within the scope of the attached claims or their equivalents.

The present disclosure can be used as a high-performance imaging device. For example, the present disclosure can be used for cameras or ranging devices.

What is claimed is:

1. An imaging device comprising:
a semiconductor substrate;
a first photoelectric converter that includes a first pixel electrode, a first counter electrode facing the first pixel electrode, and a first photoelectric conversion layer located between the first pixel electrode and the first counter electrode, the first photoelectric converter being located above the semiconductor substrate and converting first light having a wavelength in a first wavelength range into first charge;
a second photoelectric converter that is located above the first photoelectric converter and that converts second light having a wavelength in a second wavelength range into second charge;
a plug that penetrates through the first photoelectric conversion layer and that is connected to the second photoelectric converter; and
an insulating layer that is located between the first photoelectric conversion layer and the plug and that covers a side surface of the plug,
wherein the insulating layer has a tapered shape that tapers upward toward the second photoelectric converter.

2. The imaging device according to claim 1, wherein the first photoelectric conversion layer contains an organic substance.

3. The imaging device according to claim 1, wherein
the second photoelectric converter includes a second pixel electrode, a second counter electrode located above the second pixel electrode, and a second photoelectric conversion layer located between the second pixel electrode and the second counter electrode, and
the plug is connected to the second pixel electrode.

4. The imaging device according to claim 3, wherein each of the first counter electrode, the second pixel electrode, and the second counter electrode has a property of at least partially transmitting the first light.

5. The imaging device according to claim 1, further comprising:
a charge storage region that is located in the semiconductor substrate and that stores the second charge,
wherein the second photoelectric converter is connected to the charge storage region via the plug.

6. The imaging device according to claim 1, wherein an upper surface of the plug is located above an upper surface of the first photoelectric conversion layer.

7. The imaging device according to claim 1, further comprising:
a via connected to a lower end of the plug,
wherein a width of the plug is less than a width of the via.

8. An imaging device comprising:
a semiconductor substrate;
a first photoelectric converter that includes a first pixel electrode, a first counter electrode facing the first pixel electrode, and a first photoelectric conversion layer located between the first pixel electrode and the first counter electrode, the first photoelectric converter being located above the semiconductor substrate and converting first light having a wavelength in a first wavelength range into first charge;
a second photoelectric converter that is located above the first photoelectric converter and that converts second light having a wavelength in a second wavelength range into second charge; and
a plug that penetrates through the first photoelectric conversion layer and that is connected to the second photoelectric converter,
wherein the plug has a tapered shape that tapers upward toward the second photoelectric converter.

9. A method for manufacturing the imaging device according to claim 1, the method comprising:
applying a photoelectric conversion material to form the first photoelectric conversion layer.

10. A method for manufacturing an imaging device, comprising:
forming, on a semiconductor substrate, a plug and an insulating layer that covers a side surface of the plug;
processing the insulating layer so that the insulating layer tapers upward; and
forming a photoelectric conversion layer by applying a photoelectric conversion material such that a height of the photoelectric conversion material is the same as a height of the plug and the insulating layer.

11. The method according to claim 10, wherein in the forming of the plug and the insulating layer, the plug is formed by depositing the insulating layer, forming a hole in the insulating layer, and embedding a conductive material in the hole.

12. The method according to claim 11, wherein the hole is formed in the insulating layer by etching.

13. The method according to claim 10, wherein the processing of the insulating layer is performed by dry etching.

14. The method according to claim 10, wherein the forming of the photoelectric conversion layer is performed by spin coating.

15. The method according to claim 10, wherein the forming of the plug and the insulating layer, the processing of the insulating layer, and the forming of the photoelectric conversion layer are performed in this order.
